(19) United States
(12) Patent Application Publication
(10) Pub. No.: US 2022/0304149 A1
(43) Pub. Date: Sep. 22, 2022

(54) MULTILAYER CIRCUIT BOARD

(71) Applicant: 3M INNOVATIVE PROPERTIES COMPANY, St. Paul, MN (US)

(72) Inventors: YunLong Qiao, Singapore (SG); Saujit Bandhu, Singapore (SG); Kok Hoe Lee, Singapore (SG); Vincent Tan, Singapore (SG)

(21) Appl. No.: 17/596,053

(22) PCT Filed: Jun. 3, 2020
(86) PCT No.: PCT/IB2020/055250

§ 371 Date: Dec. 2, 2021

Related U.S. Application Data
(60) Provisional application No. 62/867,960, filed on Jun. 28, 2019.

(51) Int. Cl. H05K 1/02; H05K 1/11

(52) U.S. Cl. CPC H05K 1/0298; H05K 1/0245; H05K 1/0246; H05K 1/115; H05K 1/117; H05K 2201/09236; H05K 2201/09409

(57) ABSTRACT

A multilayer circuit board includes a plurality of electrically conductive rear pads for termination of a plurality of wires and a plurality of electrically conductive front pads for insertion into a connector. A plurality of pairs of substantially parallel traces extend between and connect the front pads to the rear pads. At least a first pair of traces and the front and rear pads connected thereto are disposed in a same layer of the multilayer circuit board. At least a second pair of traces is disposed in a same layer, and the rear and front pads connected thereto are disposed in a different layer of the multilayer circuit board. At least a third pair of traces are disposed in different layers of the multilayer circuit board. For each trace extending between and connecting the front and rear pads corresponding to the trace, the trace comprises no more than two vias.

### TECHNICAL FIELD

The present disclosure generally relates to multilayer circuit boards, and particularly to high speed traces routing methods for OSFP and/or QSFP DD printed circuit boards.

### BACKGROUND

Quad small form-factor pluggable (QSFP) is a widely used interface for data center external TO connection applications. As the industry is moving toward a higher data rate per cable, the quad small form-factor pluggable double density (QSFP-DD) interface and octal small form-factor pluggable (OSFP) interface have been introduced to carry double the data capacity of a QSFP cable assembly. High speed traces are routed in the circuit boards to achieve high speed data transmission at low losses.

### SUMMARY

Some aspects of the disclosure relate to a multilayer circuit board extending along a first direction between opposite front and rear edges of the circuit board. The multilayer circuit board includes a plurality of stacked layers. A plurality of electrically conductive rear pads is disposed between the front and rear edges for termination of a plurality of wires thereto. A plurality of electrically conductive front pads is disposed between the rear pads and the front edge for insertion into a connector. A plurality of pairs of substantially parallel traces extend between and connect the front pads to the rear pads. Each pair of traces is configured to transmit a differential signal. For at least a first pair of traces, the pair of traces and their corresponding rear and front pads are disposed in a same layer in the plurality of layers. For at least a second pair of traces, at least portions of the second pair of traces are disposed in a same first layer in the plurality of layers, and the rear and front pads corresponding to the second pair of traces are disposed in a same second layer in the plurality of layers, different from the first layer. For at least a third pair of traces, at least portions of the third pair of traces are disposed in a same third layer in the plurality of layers, the rear pads corresponding to the third pair of traces are disposed in a same fourth layer, different from the third layer, in the plurality of layers, and the front pads corresponding to the third pair of traces are disposed in a same fifth layer, different from the third and fourth layers. For at least one common cross-section of the plurality of pairs of traces, the common cross-section substantially perpendicular to the first direction, each pair of traces is disposed between ground traces disposed on opposite lateral sides of the pair of traces. For each trace extending between and connecting the front and rear pads corresponding to the trace, the trace includes no more than two vias.

Other aspects of the disclosure relate to a multilayer circuit board including a plurality of electrically conductive rear pads for termination of a plurality of wires thereto. The multilayer circuit board includes a plurality of electrically conductive front pads for insertion into a connector. The multilayer circuit board also includes a plurality of pairs of substantially parallel traces extending between and connecting the front pads to the rear pads. Each pair of traces is configured to transmit a differential signal. At least a first pair of traces and the front and rear pads connected thereto are disposed in a same layer of the multilayer circuit board. At least a second pair of traces is disposed in a same layer of the multilayer circuit board. The rear and front pads connected thereto are disposed in a different layer of the multilayer circuit board. At least a third pair of traces are disposed in different layers of the multilayer circuit board. In a plan top view of the multilayer circuit board, a total area of the pluralities of the rear pads, front pads, and pairs of traces is A1, and a total projected area of the pluralities of the rear pads, front pads, and pairs of traces is A2, wherein A2/A1≤0.8.

These and other aspects of the present application will be apparent from the detailed description below. In no event, however, should the above summaries be construed as limitations on the claimed subject matter, which subject matter is defined solely by the attached claims.

### BRIEF DESCRIPTION OF DRAWINGS

The various aspects of the disclosure will be discussed in greater detail with reference to the accompanying figures where,

FIGS. 1-3 schematically show different views and layout of an OSFP circuit board according to some embodiments of the disclosure;

FIG. 4 schematically shows a connector for receiving an inserting end of the circuit board;

FIG. 5 schematically shows an octal small form-factor pluggable (OSFP) connector;

FIGS. 6-8 schematically show different views and layout of an QSFP DD circuit board according to some embodiments of the disclosure;

FIG. 9 schematically shows the plurality of stacked layers in which the traces are disposed according to some aspects of the disclosure;

FIG. 10-20 schematically show the traces and the trace routing arrangement on an OSFP circuit board according to certain embodiments of the disclosure;

FIG. 21 schematically shows a cross section of the traces disposed between ground traces according to certain aspects of the disclosure;

FIG. 22A-25B schematically show different views of plurality of traces suitable for an OSFP circuit board;

FIG. 26A-29B schematically show different views of plurality of traces suitable for an QSFP DD circuit board;

FIG. 30 schematically shows the top view of the traces and pads for a QSFP DD circuit board;

FIG. 31 schematically shows the top view of the traces and pads for an OSFP circuit board;

FIG. 32A-32K schematically show cross sections of an OSFP circuit board showing routing of traces disposed between ground traces according to certain aspects of the disclosure; and

FIG. 33-36 schematically show different views of the plurality of traces suitable for an OSFP circuit board.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION OF ILLUSTRATIVE EMBODIMENTS

In the following detailed description, reference is made to the accompanying drawings that form a part hereof, and in which are shown by way of illustration several specific embodiments. It is to be understood that other embodiments are contemplated and may be made without departing from the scope or spirit of the present disclosure.

A multilayer circuit board is a circuit board made up of a plurality (e.g., at least 2, or at least 3, or several, or a large number) of wiring layers laminated with insulation layers interposed therebetween. Various electronic parts and a connector are mounted at predetermined positions of the multilayer circuit board. Each layer of the multilayer circuit board carries electrical connections, or conductive traces, which act as wires and are used to interconnect various components of the circuit. The conductive traces are bonded to, or otherwise incorporated into, an insulating substrate which mechanically supports the components. The conductive traces may be formed using any number of techniques, for example electroplating, etching, sputtering, mechanical attachment using adhesives and others explained elsewhere. The substrate may be flexible or rigid and may be fabricated from any suitable material, for example polymers, ceramics, glasses, silicon, etc.

Electrical connection between adjacent layers is achieved using “vias.” A via may be created by forming a hole between adjacent layers. In some aspects, the hole is filled with conductive material to form an electrical connection between the two adjacent layers. In a method of printed circuit board (PCB) fabrication, the conductive traces are formed separately on each layer of the multilayer circuit board. The circuit board layers of the multilayer circuit board are then stacked and aligned to each other with an electrically insulating bonding layer between adjacent layers. The assembled layers may then subjected to heat and pressure to provide a bond between adjacent layers. Via holes are then drilled in the appropriate locations which interconnect pads on successive layers. The electrical interconnect is achieved by applying a conductive material to the side walls of the via holes.

OSFP PCBs have double the data bandwidth when compared to the QSFP standard. The OSFP interface is similar to the QSFP DD interface except that it uses only one row of mating interface to achieve the 8 high speed channel design. As the number of high speed channels increases there are challenges in designing PCBs and cable arrangements in order to fit bigger size cables within the same overall size of metal shell that covers the PCB. High speed traces within the PCB should be more uniformly routed to achieve high speed transmission, with better signal integrity (SI) performance at low losses.

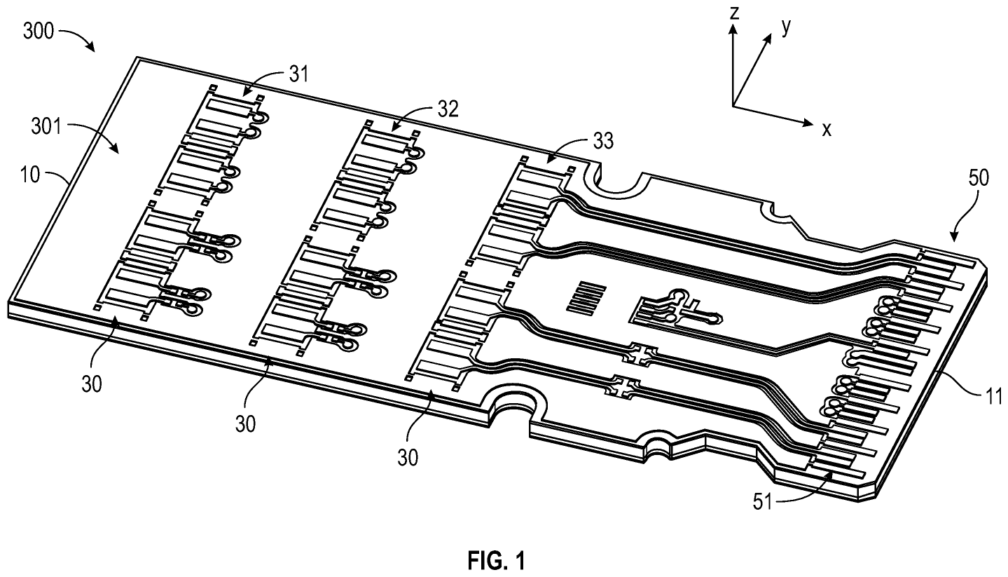

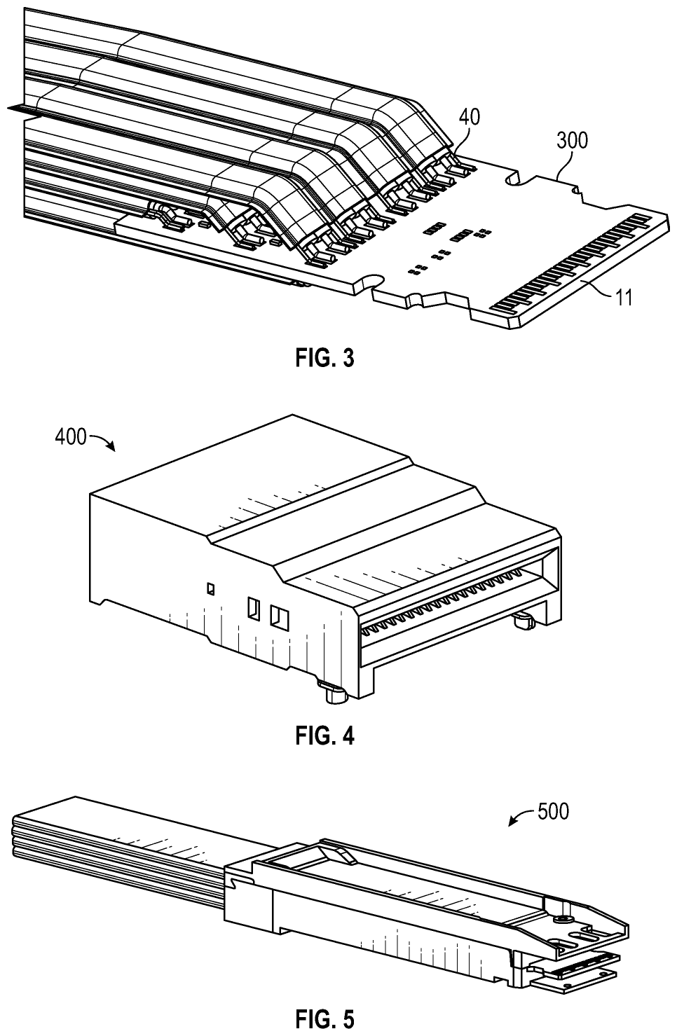

A multilayer circuit board (300), as illustrated in FIGS. 1-4, extends along a first direction (x-axis) between opposite front (11) and rear (10) edges of the circuit board. In some embodiments, the multilayer circuit board (300) may be configured to be used in an octal small form-factor pluggable (OSFP) connector (500), as shown in FIG. 5. In other embodiments, the multilayer circuit board (300) may be configured to be used in a quad small form-factor pluggable double density (QSFP-DD) connector (510), as shown in FIG. 8.

As best seen in FIG. 9, the circuit board (300) includes a plurality (20) of stacked layers (21) in which traces are routed as will be explained later.

A plurality of electrically conductive rear pads (30) is disposed between the front (11) and rear (10) edges for termination of a plurality of wires (40) thereto. In some embodiments, the plurality of electrically conductive rear pads (30) forms first (31), second (32) and third (33) rows of rear pads on an upper side (301) of the circuit board and a fourth row (34) of rear pads on a lower side (302) of the circuit board.

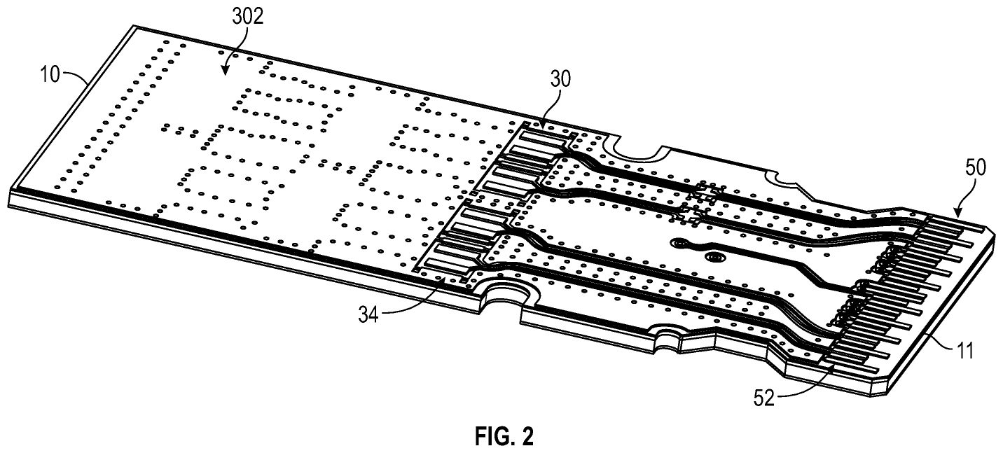

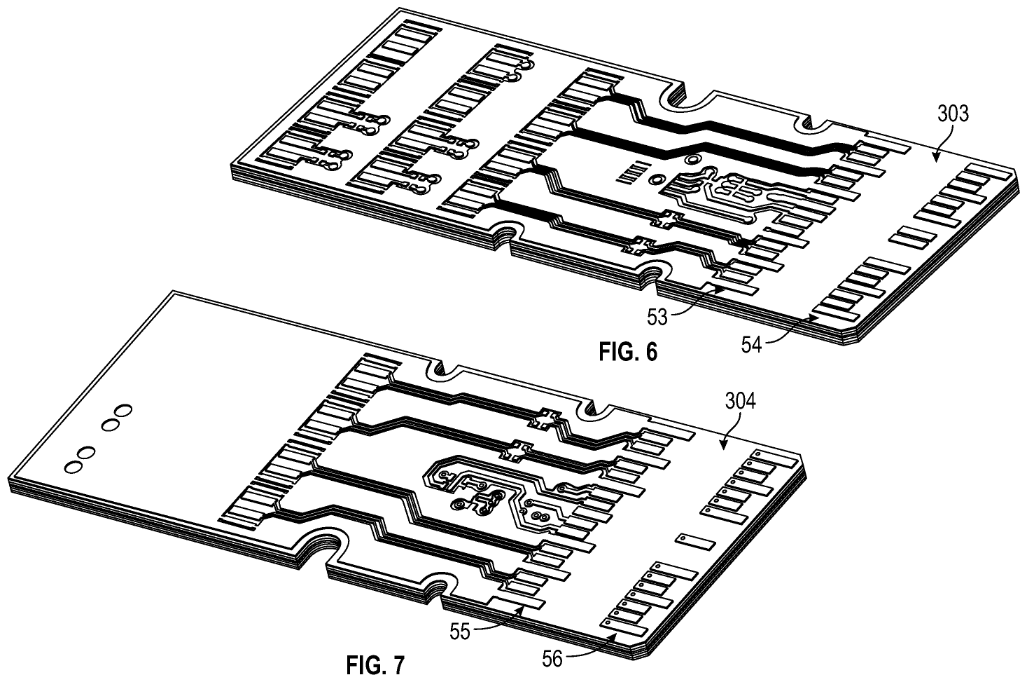

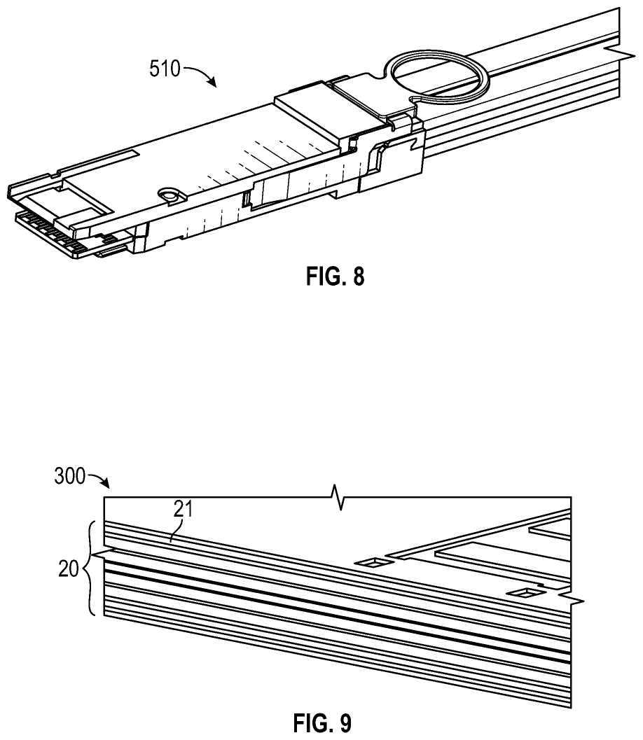

A plurality of electrically conductive front pads (50) is disposed between the rear pads (30) and the front edge (11) for insertion into a connector (400). In certain embodiments as best illustrated in FIGS. 1 and 2, in an OSFP PCB for example, the plurality of electrically conductive front pads (50) forms a first row (51) of front pads on an upper side (301) of the circuit board and a second row (52) of front pads on a lower side (302) of the circuit board. In some other embodiments as best illustrated in FIGS. 6 and 7, in a QSFP-DD PCB for example, the plurality of electrically conductive front pads (50) forms first (53) and second (54) rows of front pads on an upper side (303) of the circuit board and third (55) and fourth (56) rows of front pads on a lower side (304) of the circuit board.

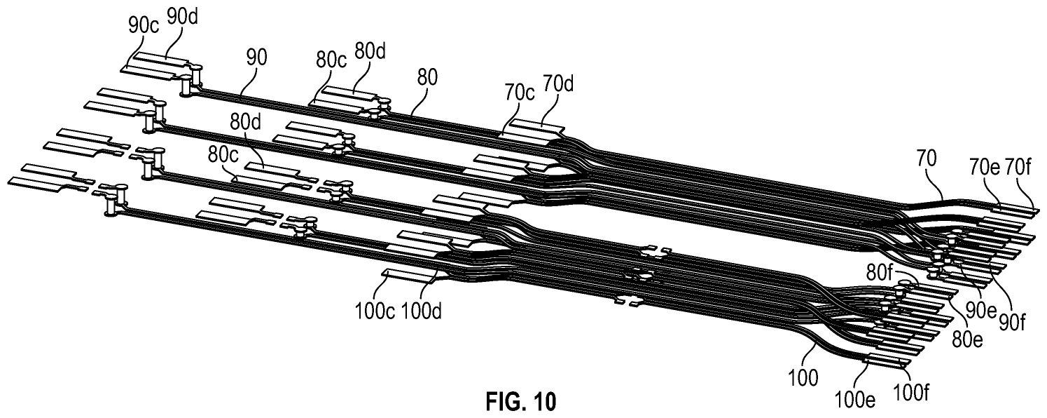

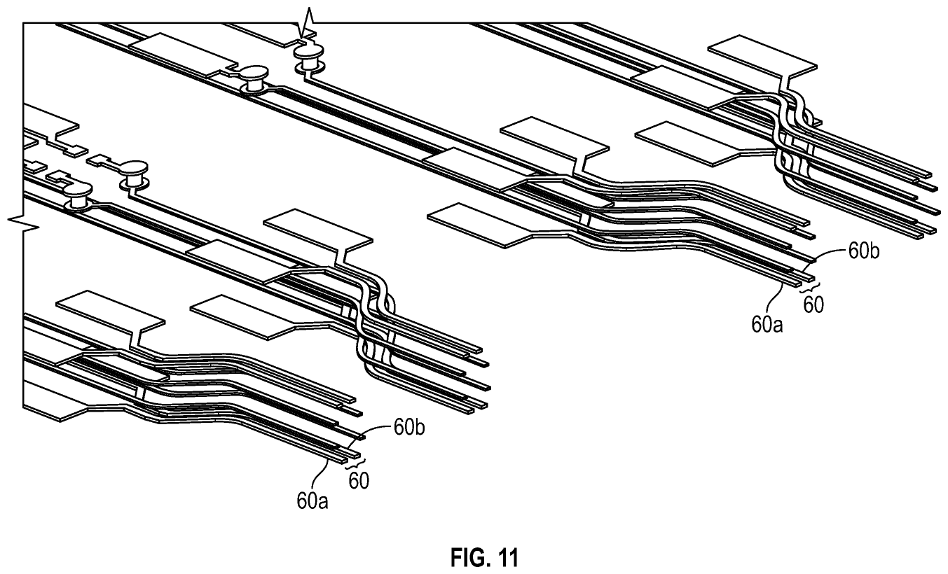

As shown in FIGS. 10 and 11, the multilayer circuit board (300) includes a plurality of pairs (60) of substantially parallel traces (60a, 60b). The substantially parallel traces (60a, 60b) extend between and connect the front pads (50) to the rear pads (30). Each pair (60) of traces is configured to transmit a differential signal, and each trace of the pair carries one of the components of the differential signal as would be described elsewhere.

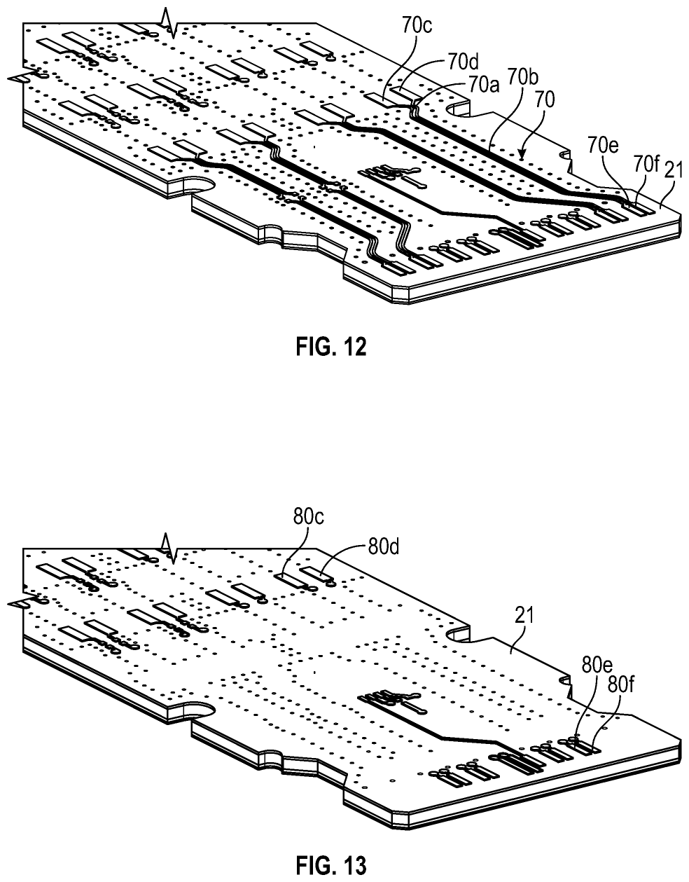

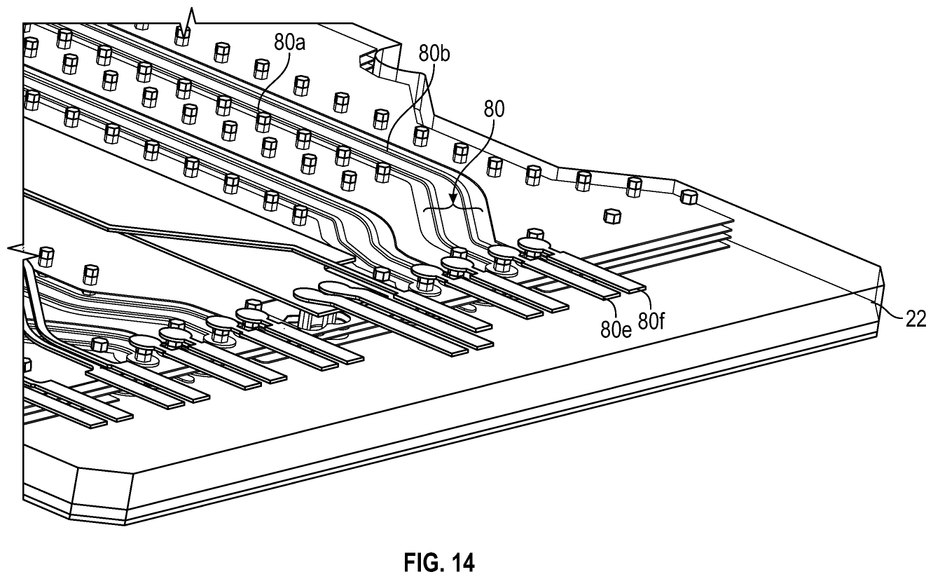

As best shown in FIG. 12, for at least a first pair (70) of traces (70a, 70b), the pair of traces and their corresponding rear (70c, 70d) and front pads (70e, 70f) are disposed in a same layer (21) in the plurality of layers (20). As best shown in FIGS. 13 and 14, for at least a second pair (80) of traces (80a, 80b), at least portions of the second pair of traces are disposed in a same first layer (22) in the plurality of layers (20), and the rear (80c, 80d) and front pads (80e, 80f) corresponding to the second pair (80) of traces (80a, 80b) are disposed in a same second layer (21) in the plurality of layers, different from the first layer (22).

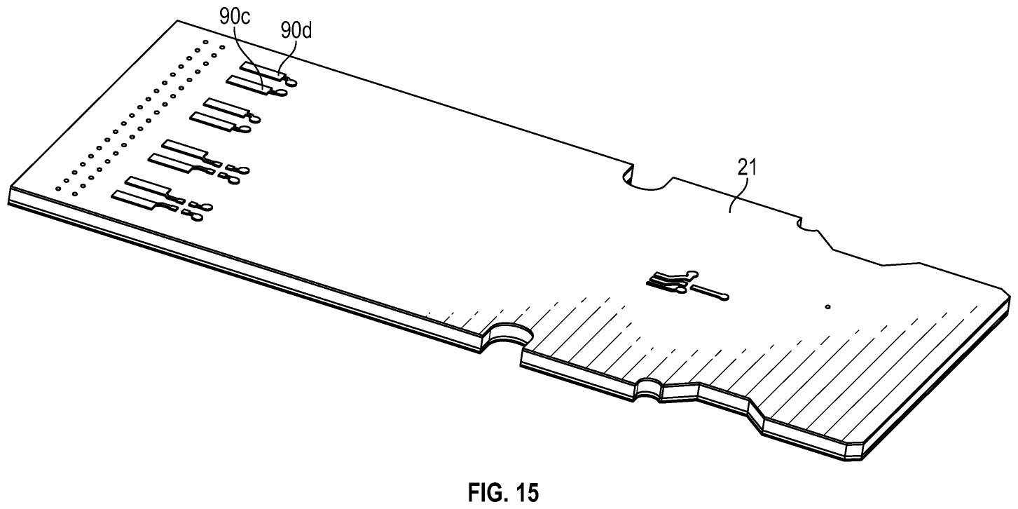

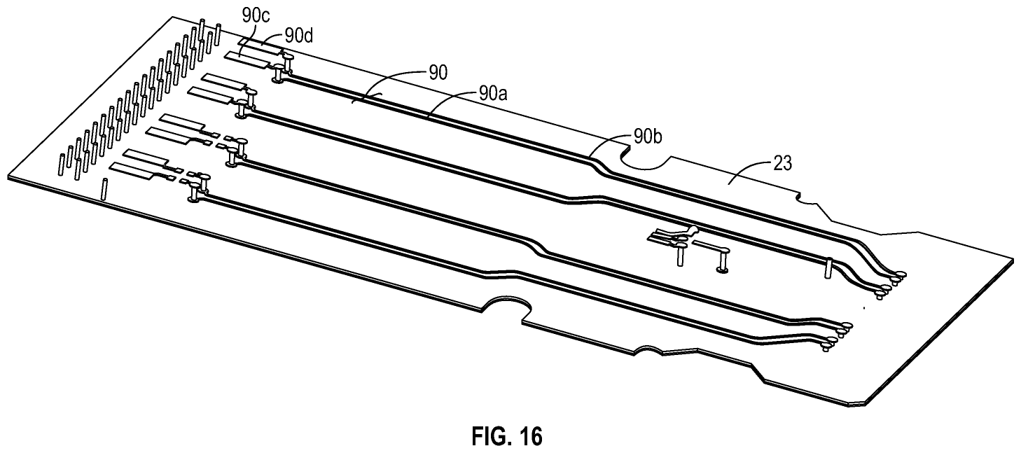

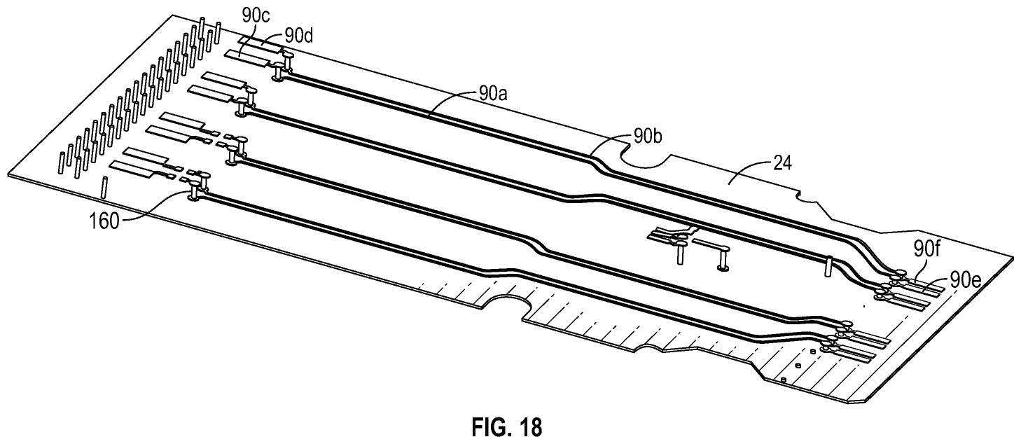

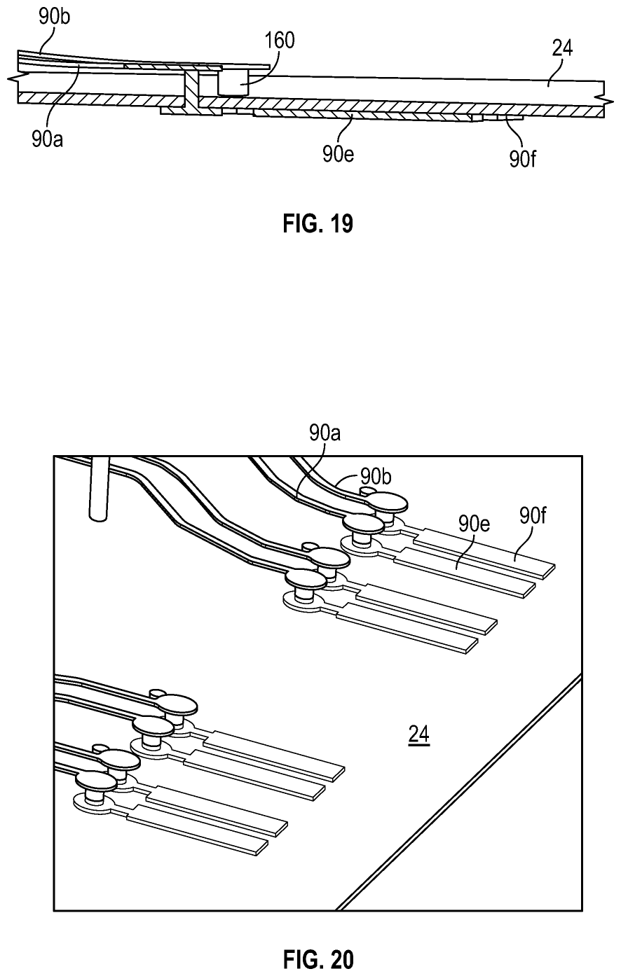

As best shown in FIGS. 15-20, at least a third pair (90) of traces are disposed in different layers (21, 23) of the multilayer circuit board. In some aspects, for at least a third pair (90) of traces (90a, 90b), at least portions of the third pair of traces (90a, 90b) are disposed in a same third layer (23) in the plurality of layers.

The rear pads (90c, 90d) corresponding to the third pair of traces (90a, 90b) are disposed in a same fourth layer (21), different from the third layer (23), in the plurality of layers. The front pads (90e, 90f) corresponding to the third pair of traces (90a, 90b) are disposed in a same fifth layer (24), different from the third and fourth layers.

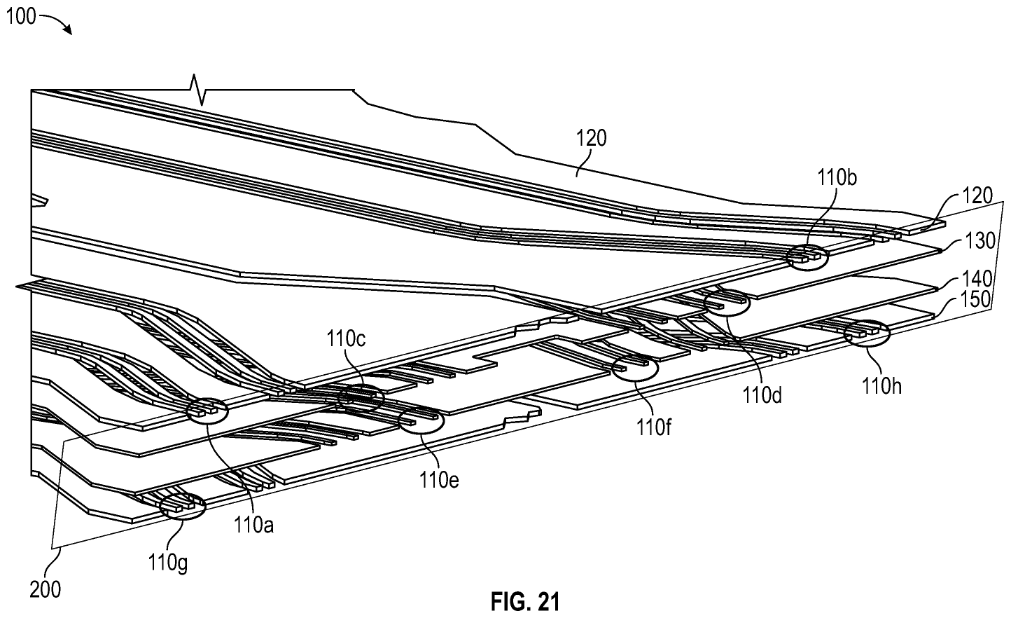

FIG. 21 shows a common cross-section (200) of the plurality of pairs of traces (110a-110g) according to an embodiment. The common cross-section (200) is substantially perpendicular to the first direction (x-axis). For at least one common cross-section (200) of the plurality of pairs of traces (110a-110g) each pair of traces is disposed between ground traces (120, 130, 140, 150) disposed on opposite lateral sides of the pair of traces. For each trace extending between and connecting the front and rear pads corresponding to the trace, the trace has no more than two vias (160) to electrically connect a trace on one layer of the PCB with one or more of the other layers of the PCB.

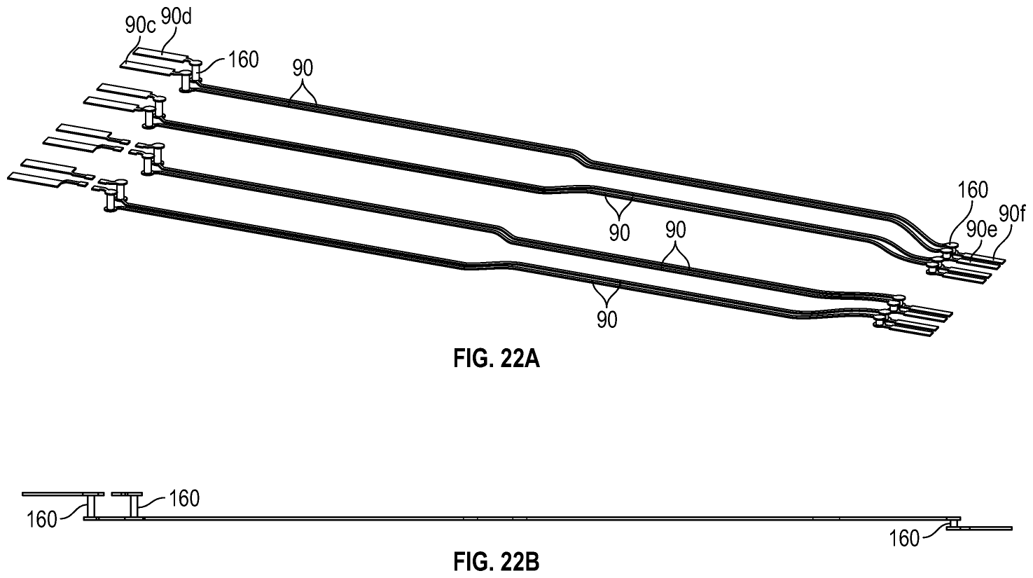

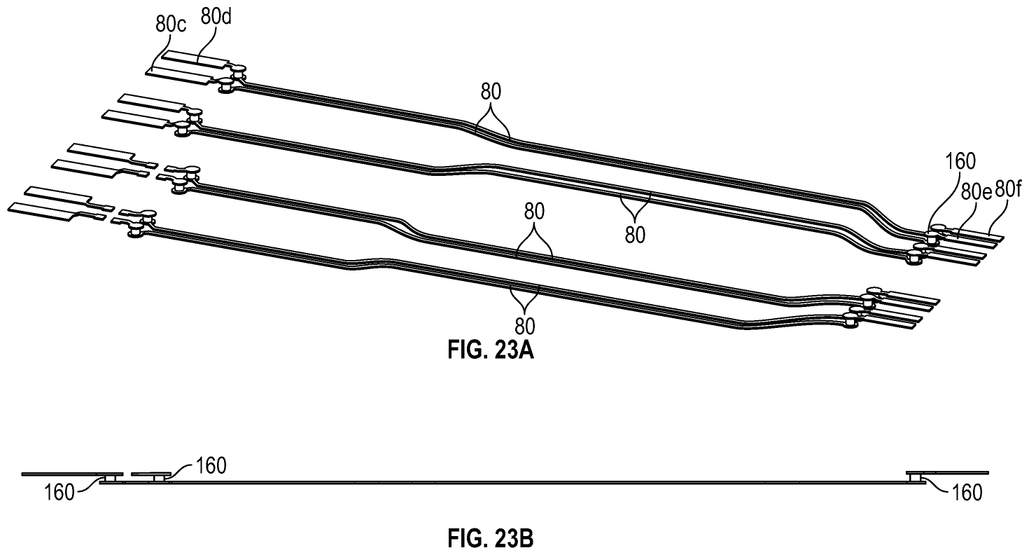

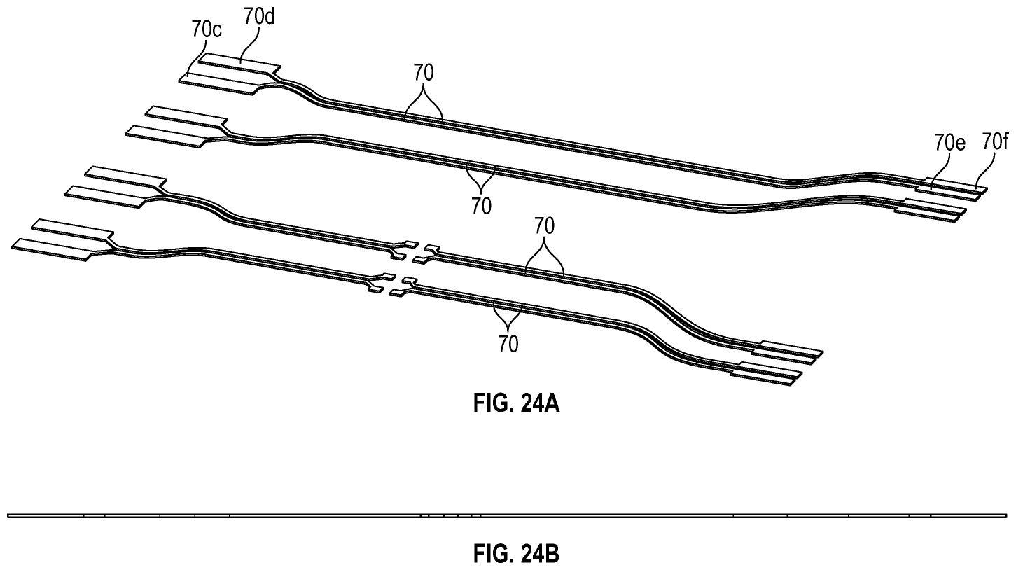

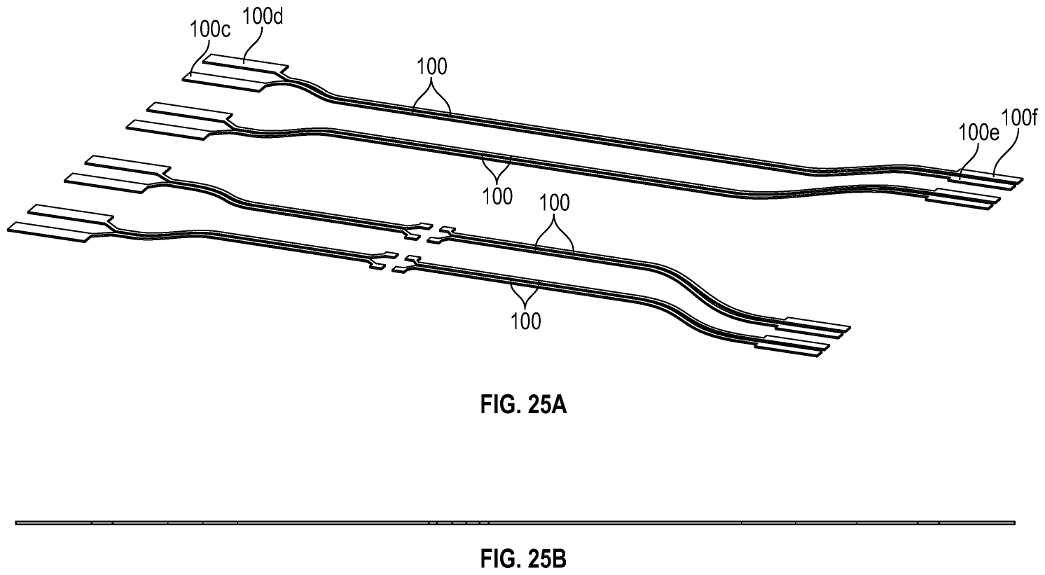

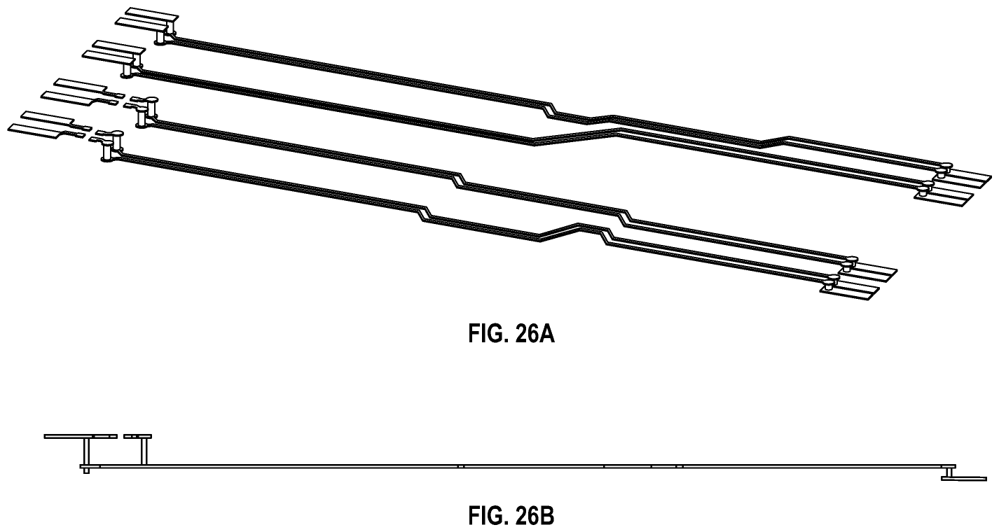

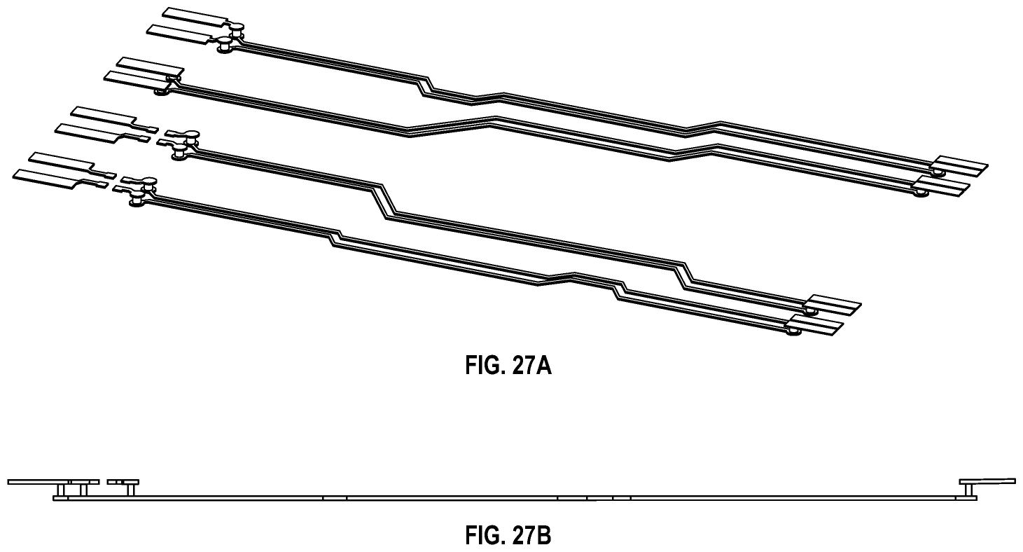

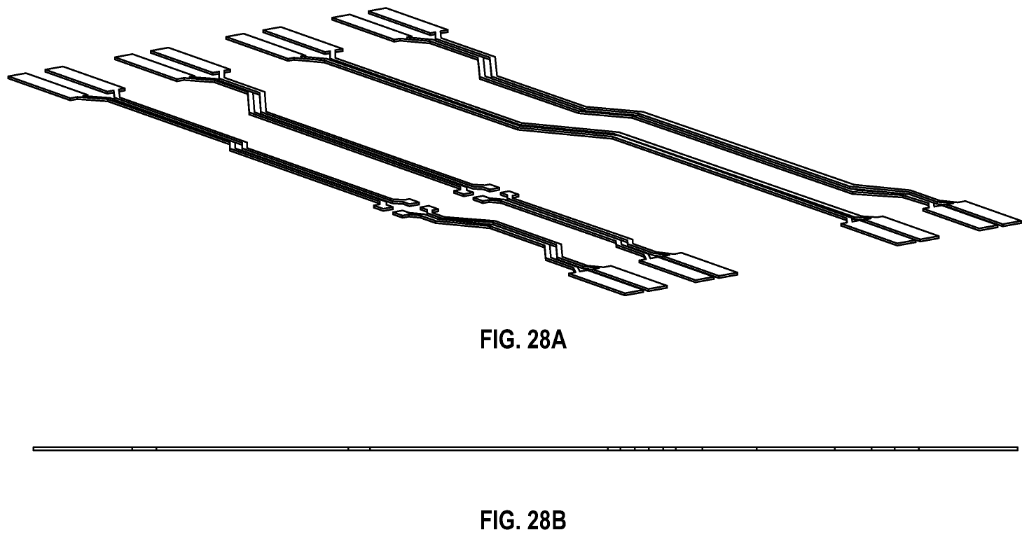

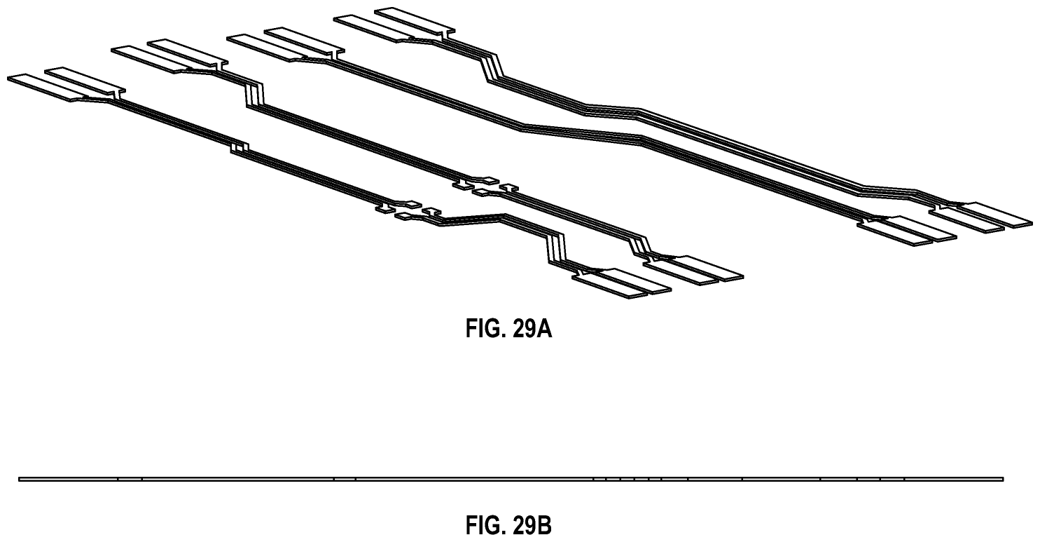

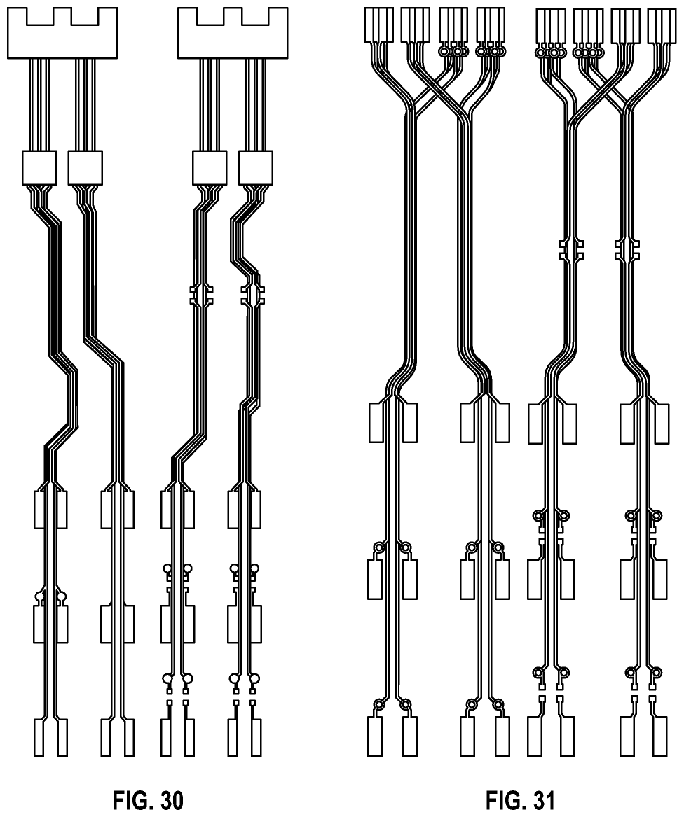

FIG. 22A-25B show different views of plurality of traces suitable for an OSFP circuit board. FIG. 26A-29B show different views of plurality of traces suitable for an QSFP DD circuit board. FIG. 30 shows the top view of the traces and pads for a QSFP DD circuit board. FIG. 31 shows the top view of the traces and pads for an OSFP circuit board.

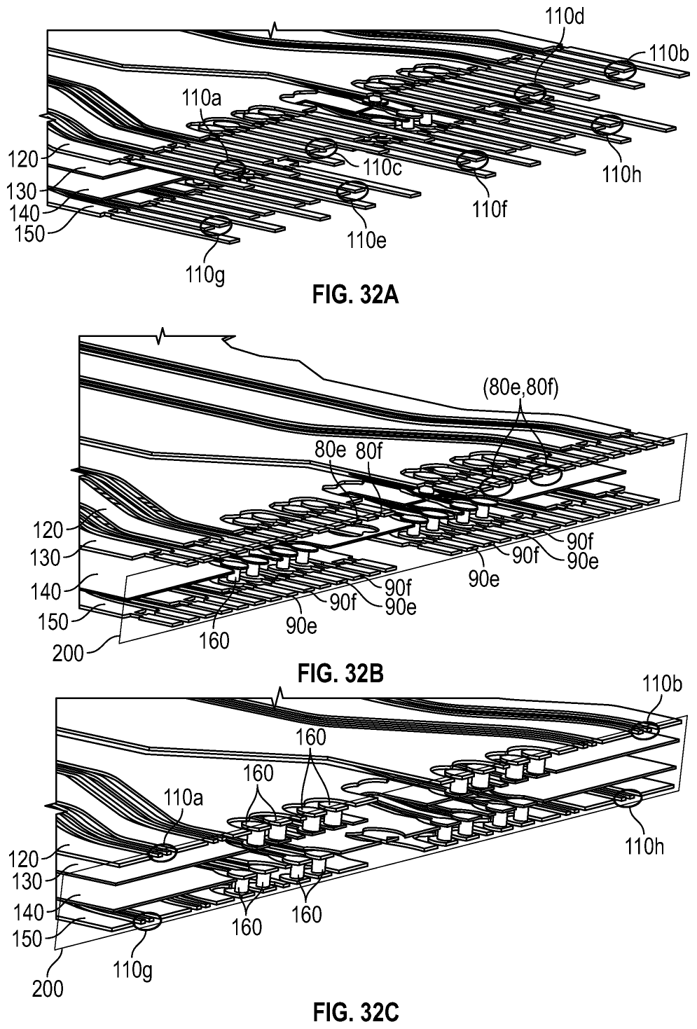

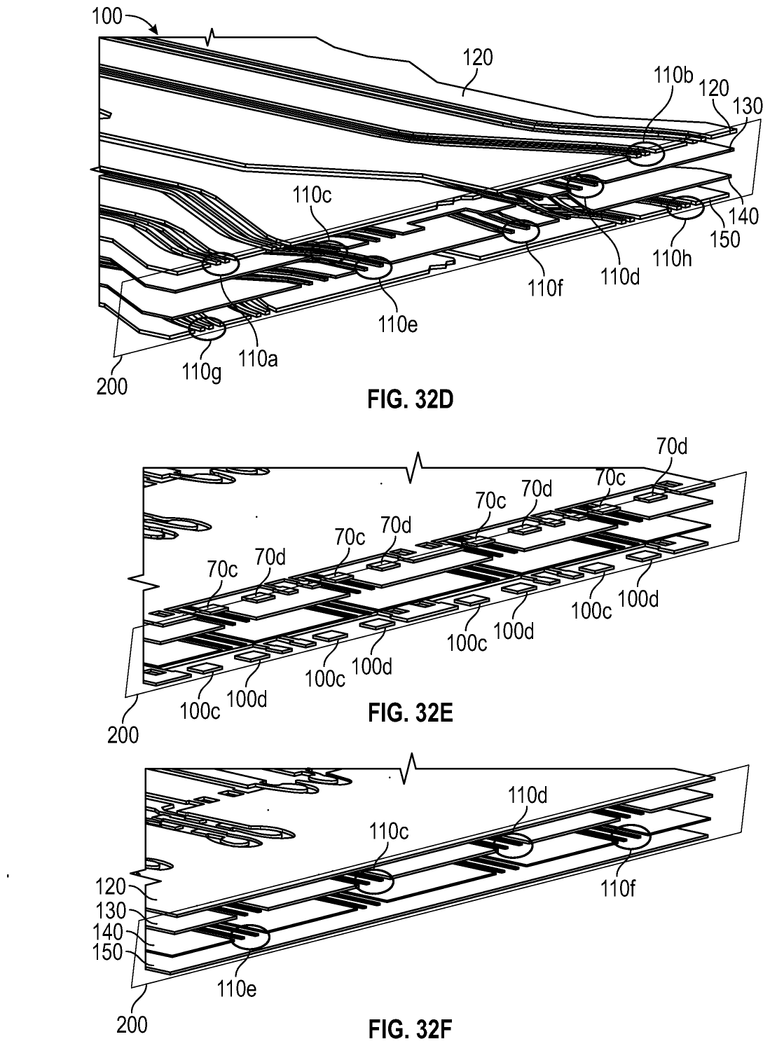

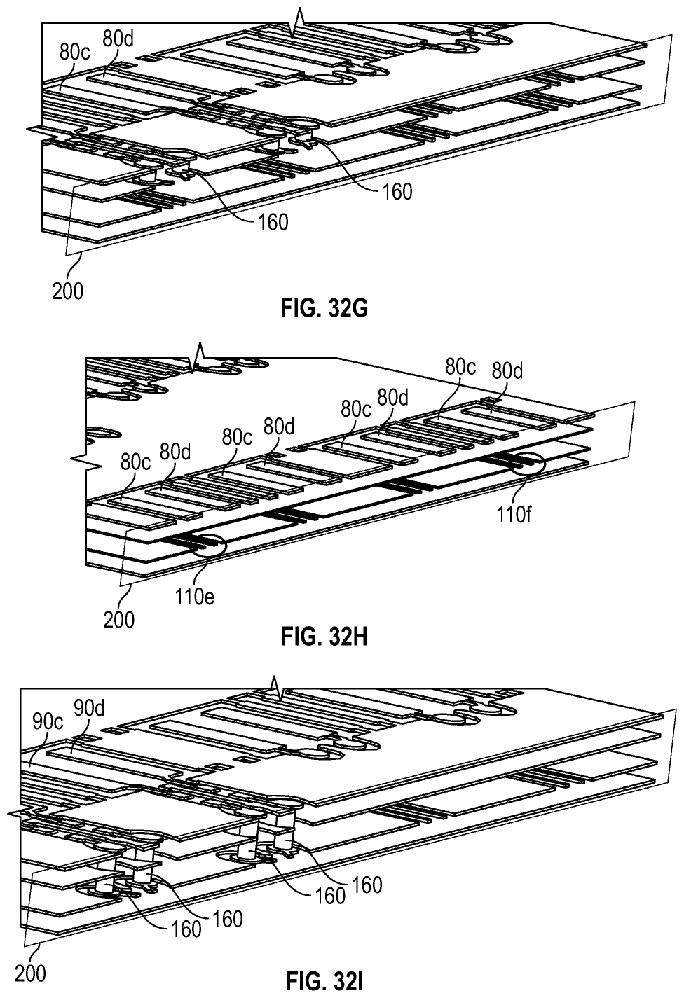

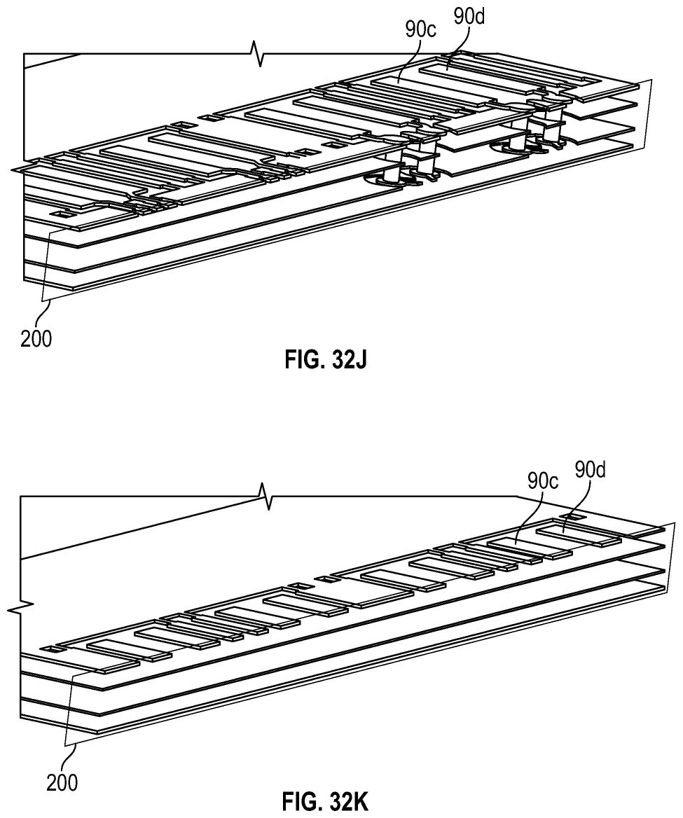

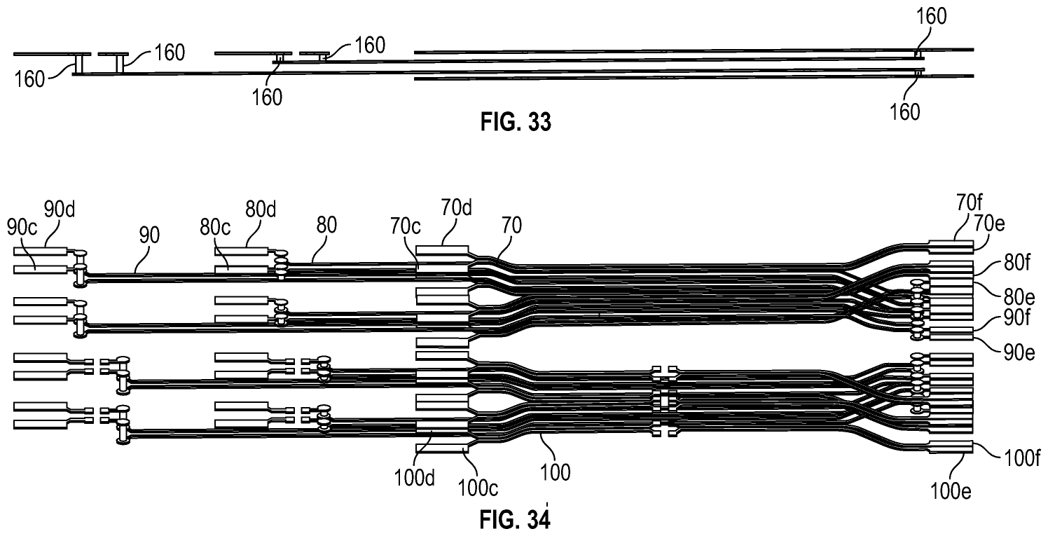

FIG. 32A shows plurality of pairs of traces, the front pads (see, e.g., FIG. 34: 70e, 70f; 80e, 80f; 90e, 90f; 100e, 1000 of each of the pairs of traces disposed between ground traces (120, 130, 140, 150) disposed on opposite lateral sides of the pair of traces.

FIGS. 32B-32K illustrate various cross sections substantially perpendicular to the first direction along an OSFP circuit board showing routing of traces disposed between ground traces.

FIGS. 32B and 32C show some cross sectionals substantially perpendicular to the first direction (x-axis). Each front pad (90e, 90f) of the third pair of traces (110e, 110f) are connected to respective vias (160). The third pair of traces (110e, 110f) are disposed such that vias (160) connect respective front pads (90e, 90f) disposed on a layer of the multilayer circuit board to a portion of the third pair of trace disposed on a different layer of the circuit board. In some aspects, the vias (160) connect the respective front pads (90e, 90f) of the third pair of traces (110e, 110f), said front pads being disposed on a layer of the multilayer circuit board, to a portion of the third pair of trace (110e, 110f) disposed on a layer above the layer on which the front pads (90e, 90f) are disposed.

Further, each front pad (80e, 80f) of the second pair of traces (110c, 110d) are connected to respective vias (160). The second pair of traces (110c, 110d) are disposed such that vias (160) connect respective front pads (80e, 80f) disposed on one layer of the multilayer circuit board to a portion of the second pair of trace disposed on a different layer of the circuit board. In some aspects, the vias (160) connect the respective front pads (80e, 80f) of the second pair of traces (110c, 110d), said front pads being disposed on a layer of the multilayer circuit board, to a portion of the second pair of trace (110c, 110d) disposed on a layer below the layer on which the front pads (80e, 80f) are disposed.

The cross sectional view of FIG. 32D shows each of the plurality of pairs of substantially parallel traces (110a-110g) disposed in respective layers of the plurality of stacked layers. Each pair of traces is disposed between ground traces (120, 130, 140, 150) disposed on opposite lateral sides of the pair of traces.

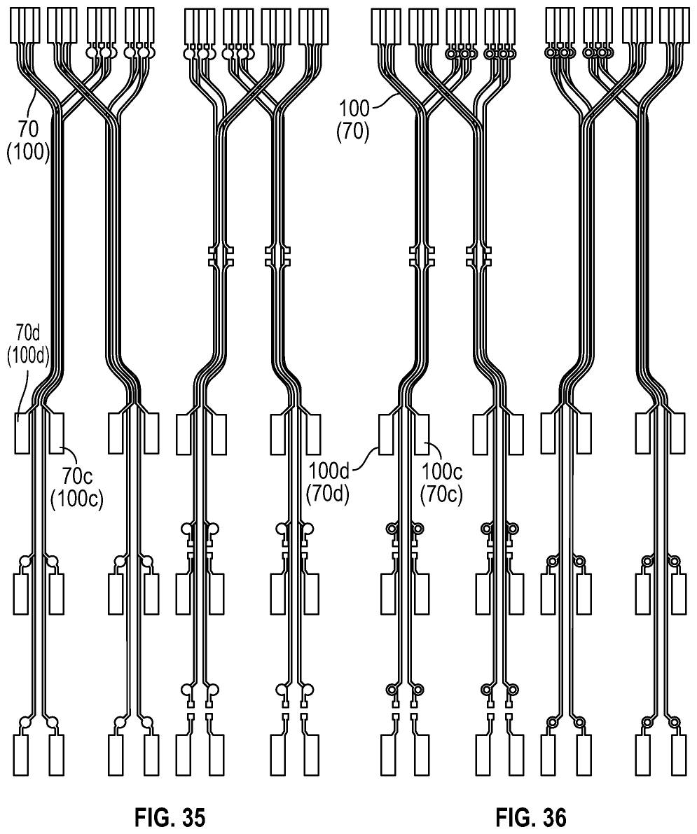

FIG. 32E illustrates a cross section of the circuit board that shows the rear pads (70c, 70d) of the first pair of traces (110a, 110b) and the rear pads (100c, 100d) of the fourth pair of traces (110g, 110h). As can be seen more clearly in FIGS. 35 and 36, in the top and bottom views of an OSFP circuit board, the rear pads (70c, 70d) of the first pair of traces (110a, 110b) and the rear pads (100c, 100d) of the fourth pair of traces (110g, 110h), and, in some embodiments, a substantial portion of the first and fourth traces, substantially overlap with each other. Further, in some embodiments, a substantial portion of the second (110c, 110d) and third (110e, 110f) traces, substantially overlap with each other.

FIGS. 32F and 32G illustrate cross sections of the circuit board showing the second (110c, 110d) and third (110e, 110f) traces disposed on different layers of the plurality of stacked layers. As best shown in FIG. 32G, the second pair of traces are disposed such that vias (160) connect a portion of the second pair of traces disposed on a layer of the multilayer circuit board to respective rear pads (80c, 80d) disposed on a different layer of the circuit board. In some aspects, the vias (160) connect the portion of the second pair of traces disposed on a layer of the multilayer circuit board to respective rear pads (80c, 80d) disposed on a layer above the layer on which the portion of the second pair of traces is disposed.

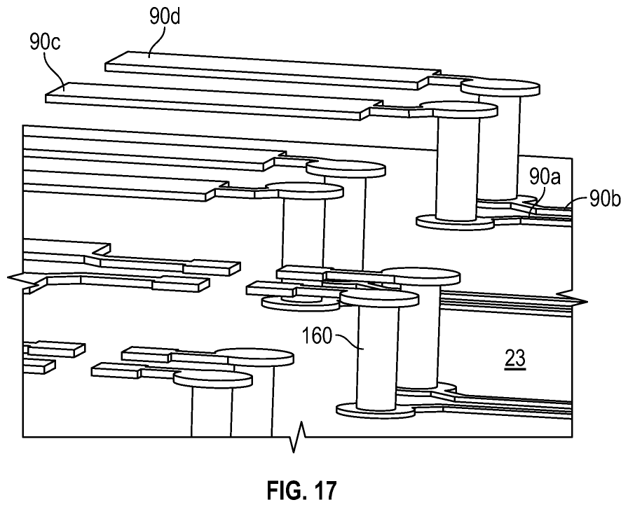

FIG. 32H shows a further cross section of the circuit board. FIG. 32H shows rear pads (80c, 80d) of the second pair of traces. The third pair of traces (110e, 110f) extend beyond the rear pads (80c, 80d) of the second pair of traces. As can be seen in FIGS. 32I to 32J, the third pair of traces are disposed such that vias (160) connect a portion of the third pair of traces disposed on a layer of the multilayer circuit board to respective rear pads (90c, 90d) disposed on a different layer of the circuit board. In some aspects, the vias (160) connect the portion of the third pair of traces disposed on a layer of the multilayer circuit board to respective rear pads (90c, 90d) disposed on a layer above the layer on which the portion of the third pair of traces is disposed. FIG. 17 shows the arrangement of the portion of the third pair of traces (90a, 90b), the via (160) and the rear pads (90c, 90d) of the third pair of traces as described above.

FIG. 32K illustrates a further cross section of the circuit board showing rear pads (90c, 90d) of the third pair of traces.

In other aspects of the disclosure, in a plan top view of the multilayer circuit board, a total area of the pluralities of the rear pads, front pads, and pairs of traces is A1. A total projected area of the pluralities of the rear pads, front pads, and pairs of traces is A2. The projected area A2 is the area of overlap of the traces in the plan view. In some embodiments, A2/A1≤0.8. In other embodiments, A2/A1≤0.75, or A2/A1≤0.70. In some other embodiments, A2/A1 is about 0.64 and in some other embodiments, A2/A1 is about 0.65.

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific Embodiments shown and described without departing from the scope of the present disclosure. This application is intended to cover any adaptations or variations of the specific Embodiments discussed herein. Therefore, it is intended that this disclosure be limited only by the claims and the equivalents thereof.

1. A multilayer circuit board extending along a first direction between opposite front and rear edges of the circuit board and comprising:
a plurality of stacked layers;
a plurality of electrically conductive rear pads disposed between the front and rear edges for termination of a plurality of wires thereto;
a plurality of electrically conductive front pads disposed between the rear pads and the front edge for insertion into a connector; and
a plurality of pairs of substantially parallel traces extending between and connecting the front pads to the rear pads, each pair of traces configured to transmit a differential signal, wherein for at least:
a first pair of traces, the pair of traces and their corresponding rear and front pads are disposed in a same layer in the plurality of layers;
a second pair of traces, at least portions of the second pair of traces are disposed in a same first layer in the plurality of layers, and the rear and front pads corresponding to the second pair of traces are disposed in a same second layer in the plurality of layers, different from the first layer;
a third pair of traces, at least portions of the third pair of traces are disposed in a same third layer in the plurality of layers, the rear pads corresponding to the third pair of traces are disposed in a same fourth layer, different from the third layer, in the plurality of layers, and the front pads corresponding to the third pair of traces are disposed in a same fifth layer, different from the third and fourth layers;
one common cross-section of the plurality of pairs of traces, the common cross-section substantially perpendicular to the first direction, each pair of traces is disposed between ground traces disposed on opposite lateral sides of the pair of traces; and
wherein, for each trace extending between and connecting the front and rear pads corresponding to the trace, the trace comprises no more than two vias.

2. The multilayer circuit board of claim 1, wherein the plurality of electrically conductive rear pads forms first, second and third rows of rear pads on an upper side of the circuit board and a fourth row of rear pads on a lower side of the circuit board.

3. The multilayer circuit board of claim 1, wherein the plurality of electrically conductive front pads forms a first row of front pads on an upper side of the circuit board and a second row of front pads on a lower side of the circuit board.

4. The multilayer circuit board of claim 1, wherein the plurality of electrically conductive front pads forms first and second rows of front pads on an upper side of the circuit board and third and fourth rows of front pads on a lower side of the circuit board.

5. The multilayer circuit board of claim 1 configured to be used in an octal small form-factor pluggable (OSFP) connector.

6. The multilayer circuit board of claim 1 configured to be used in a quad small form-factor pluggable double density (QSFP-DD) connector.

7. A multilayer circuit board comprising:
a plurality of electrically conductive rear pads for termination of a plurality of wires thereto;
a plurality of electrically conductive front pads for insertion into a connector; and
a plurality of pairs of substantially parallel traces extending between and connecting the front pads to the rear pads, each pair of traces configured to transmit a differential signal, wherein:
at least a first pair of traces and the front and rear pads connected thereto are disposed in a same layer of the multilayer circuit board;
at least a second pair of traces is disposed in a same layer of the multilayer circuit board, and the rear and front pads connected thereto are disposed in a different layer of the multilayer circuit board; and
at least a third pair of traces are disposed in different layers of the multilayer circuit board;
wherein in a plan top view of the multilayer circuit board:
a total area of the pluralities of the rear pads, front pads, and pairs of traces is A1; and
a total projected area of the pluralities of the rear pads, front pads, and pairs of traces is A2, A2/A1≤0.8.

8. The multilayer circuit board of claim 7, wherein A2/A1≤0.75.

9. The multilayer circuit board of claim 1, wherein for at least one common cross-section of the plurality of pairs of traces, the common cross-section substantially perpendicular to the first direction, each pair of traces is disposed between ground traces disposed on opposite lateral sides of the pair of traces.

10. The multilayer circuit board of claim 1, wherein for each trace extending between and connecting the front and rear pads corresponding to the trace, the trace comprises no more than two vias.
